(19) United States
(12) Patent Application Publication
(10) Pub. No.: US 2026/0005116 A1
(43) Pub. Date: Jan. 1, 2026

(54) SEMICONDUCTOR PACKAGING SUBSTRATE STRUCTURE AND MANUFACTURING METHOD THEREOF

(71) Applicant: PHOENIX PIONEER TECHNOLOGY CO., LTD., Hsinchu County (TW)

(72) Inventor: Wen-Hung HU, Hsinchu County (TW)

(21) Appl. No.: 19/250,064

(22) Filed: Jun. 26, 2025

(30) Foreign Application Priority Data
Jun. 26, 2024 (TW) 113123847

(51) Int. Cl. H01L 23/498; H01L 21/48

(52) U.S. Cl. CPC H01L 23/49827; H01L 21/4853; H01L 21/486; H01L 23/49838; H01L 23/49866

(57) ABSTRACT

A semiconductor packaging substrate structure is provided and includes a circuit build-up structure and at least one winding spiral coil. The circuit build-up structure has at least one first patterned wiring layer, a first dielectric layer, a second dielectric layer, and a third dielectric layer. The winding spiral coil is composed of an enameled wire. The first patterned wiring layer is embedded in the third dielectric layer. The winding spiral coil is embedded in the second dielectric layer. The first patterned wiring layer and the winding spiral coil are electrically connected to each other. A manufacturing method of the semiconductor packaging substrate structure is further provided.

### CROSS-REFERENCE TO RELATED APPLICATIONS

This application claims the benefit of TW patent application No. 113123847, filed on Jun. 26, 2024 in Taiwan, the entire contents of which are incorporated herein by reference.

### BACKGROUND

### 1. Technical Field

The present disclosure relates to a semiconductor packaging substrate structure, and more particularly, to a semiconductor packaging substrate structure in which a three-dimensional winding spiral coil can be embedded by using packaging technology, and a manufacturing method thereof.

### 2. Description of Related Art

Existing plate coils are multi-layer build-up plate structures, which need to be stacked layer by layer, and then a protective layer, metalized surface treatment pads, etc. are fabricated to make external electrical connections. As shown in FIG. 1, the specific fabrication process of an existing multi-layer plate coil 1 is as follows. First, a metal substrate 10 having a circuit layer 101 is provided, a photoresist (not shown) is formed on the metal substrate 10, and a first coil 111 electrically connected to the circuit layer 101 is formed by electroplating in the photoresist by means of a patterning process. After removing the photoresist, a first insulating layer 121 is formed on the metal substrate 10 such that the first insulating layer 121 covers the first coil 111. Subsequently, a first dielectric layer 131 is formed on the first insulating layer 121, and openings are formed in the first dielectric layer 131. Thereafter, a first conductive layer 141 electrically connected to the first coil 111 is formed in the openings. The aforesaid process of manufacturing the first coil 111 and the first conductive layer 141 may be repeated sequentially as desired to form a second coil 112, a second insulating layer 122, a second dielectric layer 132, a second conductive layer 142, a third coil 113, a third insulating layer 123, a third dielectric layer 133, and a third conductive layer 143, respectively. Finally, a protective layer 15 is formed on the third dielectric layer 133 and the metal substrate 10, and an opening 150 may be formed on the protective layer 15 to expose the circuit layer 101, and an electrode pad 16 may be formed in the opening 150 and on the exposed circuit layer 101.

The manufacturing process of the existing multi-layer plate coil 1 described above is too cumbersome, the manufacturing time is too long, the cost is too high, and the thrust of the completed multi-layer plate coil 1 is only 60%-70% of that of the wound coil. In addition, if the existing multi-layer plate coil 1 is inadvertently stacked on and combined with a layer of failed coils (e.g., any of the first coil 111, the second coil 112, and the third coil 113) during the manufacturing process, the entire multi-layer plate coil 1 will fail and be scrapped, resulting in poor production yield.

Therefore, how to overcome various problems of the above-mentioned prior art has become a difficult problem urgently to be overcome in the industry.

### SUMMARY

In view of the various deficiencies of the prior art, the present disclosure provides a semiconductor packaging substrate structure with winding spiral coils. The semiconductor packaging substrate structure comprises: a circuit build-up structure comprising at least one first patterned wiring layer, a first dielectric layer, a second dielectric layer, and a third dielectric layer, wherein the second dielectric layer is stacked and bonded to an upper surface of the first dielectric layer, the third dielectric layer is stacked and bonded to an upper surface of the second dielectric layer, a first patterned wiring layer is embedded within the third dielectric layer, and an upper surface of the first patterned wiring layer is exposed from an upper surface of the third dielectric layer; and at least one winding spiral coil provided on the upper surface of the first dielectric layer, embedded within the second dielectric layer, and electrically connected to the first patterned wiring layer, wherein a body of the winding spiral coil is an enameled copper wire, an enameled aluminum wire, or an enameled alloy wire.

In the aforementioned semiconductor packaging substrate structure, the present disclosure further comprises: a plurality of limit pillars embedded within the second dielectric layer, wherein the plurality of limit pillars are framed around a circumference of the winding spiral coil.

In the aforementioned semiconductor packaging substrate structure, the present disclosure further comprises: a plurality of limit pads embedded within the first dielectric layer, wherein the plurality of limit pillars are bonded to and erected on upper surfaces of the plurality of limit pads.

In the aforementioned semiconductor packaging substrate structure, the present disclosure further comprises: at least one limit opening formed within the second dielectric layer and accordingly accommodating the winding spiral coil, wherein the limit opening further comprises a fourth dielectric layer covering the winding spiral coil and filling the limit opening.

In the aforementioned semiconductor packaging substrate structure, the present disclosure further comprises: at least one second patterned wiring layer embedded within the first dielectric layer, and at least one conductive pillar embedded within the second dielectric layer, wherein an upper surface and a lower surface of the second patterned wiring layer are exposed from the upper surface and a lower surface of the first dielectric layer, respectively, and the conductive pillar is electrically connected to the first patterned wiring layer and the second patterned wiring layer.

In the aforementioned semiconductor packaging substrate structure, the present disclosure further comprises: at least one bonding layer formed between the winding spiral coil and the first dielectric layer and bonding the winding spiral coil and the first dielectric layer, wherein the bonding layer is an adhesive layer.

The present disclosure also provides a method of manufacturing a semiconductor packaging substrate structure with winding spiral coils, the method comprises: providing a carrier board having a rigidity; forming a first dielectric layer on the carrier board; providing at least one winding spiral coil, and disposing the winding spiral coil on the first dielectric layer, wherein a body of the winding spiral coil is an enameled copper wire, an enameled aluminum wire, or an enameled alloy wire; forming a second dielectric layer on the first dielectric layer to cover the winding spiral coil; removing a portion of the second dielectric layer to expose two ends of the winding spiral coil; forming a first patterned wiring layer by electroplating on the second dielectric layer by means of a patterned exposure and development process, wherein the first patterned wiring layer is electrically connected to the two ends of the winding spiral coil; forming a third dielectric layer on the second dielectric layer to cover the first patterned wiring layer; removing a portion of the third dielectric layer to expose an upper surface of the first patterned wiring layer; and removing the carrier board.

In the aforementioned method of manufacturing the semiconductor packaging substrate structure, the present disclosure further comprises: prior to forming the first dielectric layer, performing a patterned exposure and development process to form a second patterned wiring layer by electroplating, and after forming the first dielectric layer to cover the second patterned wiring layer, removing a portion of the first dielectric layer to expose an upper surface of the second patterned wiring layer from an upper surface of the first dielectric layer; prior to providing the winding spiral coil, performing a patterned exposure and development process to form at least one conductive pillar by electroplating, wherein the conductive pillar is electrically connected to the second patterned wiring layer; exposing an end surface of the conductive pillar while removing the portion of the second dielectric layer to expose the two ends of the winding spiral coil; and electrically connecting the first patterned wiring layer to the two ends of the winding spiral coil and electrically connecting the first patterned wiring layer to the conductive pillar while forming the first patterned wiring layer by electroplating.

In the aforementioned method of manufacturing the semiconductor packaging substrate structure, the present disclosure further comprises: prior to forming the first dielectric layer, performing a patterned exposure and development process to form a plurality of limit pads by electroplating, and after forming the first dielectric layer to cover the carrier board and the plurality of limit pads, removing a portion of the first dielectric layer to expose upper surfaces of the plurality of limit pads from an upper surface of the first dielectric layer; and forming a plurality of limit pillars by electroplating on the upper surfaces of the plurality of limit pads by means of a patterned exposure and development process, wherein an area surrounded by the plurality of limit pillars defines a setting area of the winding spiral coil.

In the aforementioned method of manufacturing the semiconductor packaging substrate structure, the present disclosure further comprises: forming a second patterned wiring layer by electroplating while forming the plurality of limit pads by electroplating, and exposing an upper surface of the second patterned wiring layer while removing the portion of the first dielectric layer to expose the upper surfaces of the plurality of limit pads; forming at least one conductive pillar on the upper surface of the second patterned wiring layer by electroplating while forming the plurality of limit pillars by electroplating; exposing an end surface of the conductive pillar while removing the portion of the second dielectric layer to expose the two ends of the winding spiral coil; and electrically connecting the first patterned wiring layer to the two ends of the winding spiral coil and electrically connecting the first patterned wiring layer to the conductive pillar while forming the first patterned wiring layer by electroplating.

The present disclosure further provides a method of manufacturing a semiconductor packaging substrate structure, the method comprises: providing a carrier board having a rigidity; forming a first dielectric layer on the carrier board; forming at least one temporary bump on an upper surface of the first dielectric layer by a patterned exposure and development process; forming a second dielectric layer on the first dielectric layer and the temporary bump, wherein the temporary bump is embedded within the second dielectric layer; removing a portion of the second dielectric layer to expose an upper surface of the temporary bump; removing the temporary bump to form at least one limit opening in the second dielectric layer; providing at least one winding spiral coil, and disposing the winding spiral coil within the limit opening, wherein a body of the winding spiral coil is an enameled copper wire, an enameled aluminum wire, or an enameled alloy wire; forming a fourth dielectric layer on the second dielectric layer, wherein the limit opening is filled by the fourth dielectric layer, and the winding spiral coil is embedded within the fourth dielectric layer; removing a portion of the fourth dielectric layer to expose two ends of the winding spiral coil and an upper surface of the second dielectric layer; forming a first patterned wiring layer by electroplating on the upper surface of the second dielectric layer and an upper surface of the fourth dielectric layer by means of a patterned exposure and development process, wherein a portion of the first patterned wiring layer is electrically connected to the two ends of the winding spiral coil; forming a third dielectric layer on the upper surface of the second dielectric layer and the upper surface of the fourth dielectric layer, wherein the first patterned wiring layer is embedded within the third dielectric layer; removing a portion of the third dielectric layer to expose an upper surface of the first patterned wiring layer; and removing the carrier board.

In the aforementioned method of manufacturing the semiconductor packaging substrate structure, the temporary bump is a dry film photoresist bump formed by the patterned exposure and development process.

In the aforementioned method of manufacturing the semiconductor packaging substrate structure, the temporary bump is a metal bump formed by electroplating by means of the patterned exposure and development process.

In the aforementioned method of manufacturing the semiconductor packaging substrate structure, the present disclosure further comprises: prior to forming the first dielectric layer, performing a patterned exposure and development process to form a second patterned wiring layer by electroplating, and after forming the first dielectric layer to cover the second patterned wiring layer, removing a portion of the first dielectric layer to expose an upper surface of the second patterned wiring layer from the upper surface of the first dielectric layer; prior to forming the second dielectric layer, forming at least one conductive pillar electrically connected to the second patterned wiring layer by electroplating; exposing an end surface of the conductive pillar while removing the portion of the second dielectric layer to expose the upper surface of the temporary bump; and electrically connecting the first patterned wiring layer to the two ends of the winding spiral coil and electrically connecting the first patterned wiring layer to the conductive pillar while forming the first patterned wiring layer by electroplating.

In the aforementioned method of manufacturing the semiconductor packaging substrate structure, the present disclosure further comprises: prior to providing the winding spiral coil, forming at least one bonding layer on the upper surface of the first dielectric layer in the setting area of the winding spiral coil for correspondingly bonding the winding spiral coil, wherein the bonding layer is an adhesive layer.

In summary, in the semiconductor packaging substrate structure and the manufacturing method thereof, by directly providing the winding spiral coil, the present disclosure can avoid the time-consuming and costly problem of manufacturing plate coils by the conventional circuit build-up method. The winding spiral coil of the present disclosure can be manufactured independently in advance and then disposed into the semiconductor packaging substrate structure, thereby avoiding the problem of poor product yield caused by the failure of the prior art single coil. Moreover, in addition to directly disposing the winding spiral coil in the semiconductor packaging substrate structure, the present disclosure can also dispose limit pillars or limit openings in the dielectric layer in order to dispose the winding spiral coils accurately, thereby effectively avoiding misalignment of the winding spiral coils. The semiconductor packaging substrate structure of the present disclosure with winding spiral coils is superior in performance to multiple layers of plate coils and can be effectively applied to coil structures in optical image stabilization voice coil motors (OIS VCMs), loudspeakers, miniature motors, miniature inductors, and protective devices for electronic components.

### BRIEF DESCRIPTION OF THE DRAWINGS

FIG. 1 is a schematic cross-sectional view of a conventional plate coil.

FIG. 2A to FIG. 2H are schematic cross-sectional views illustrating a manufacturing method of a semiconductor packaging substrate structure according to a first embodiment of the present disclosure.

FIG. 3A to FIG. 3H are schematic cross-sectional views illustrating a manufacturing method of a semiconductor packaging substrate structure according to a second embodiment of the present disclosure.

FIG. 4A to FIG. 4I are schematic cross-sectional views illustrating a manufacturing method of a semiconductor packaging substrate structure according to a third embodiment of the present disclosure.

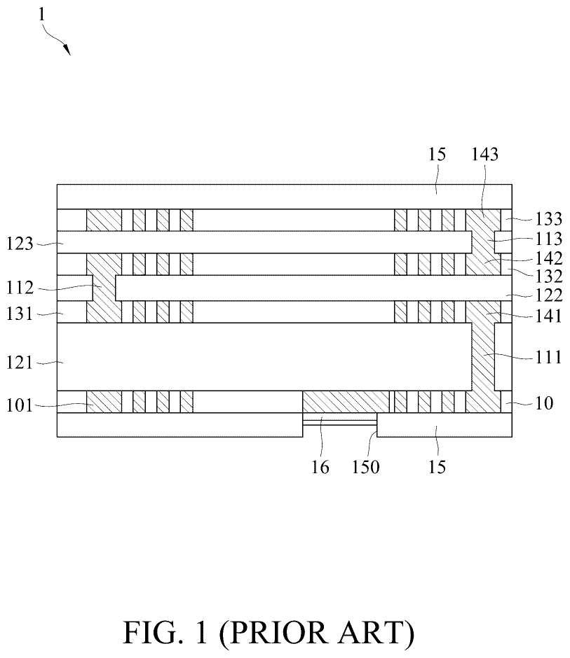

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “at least one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

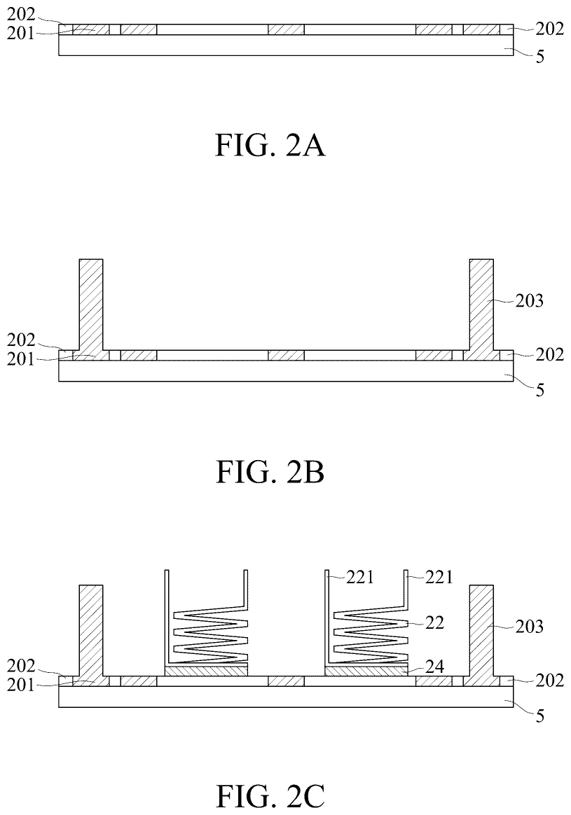

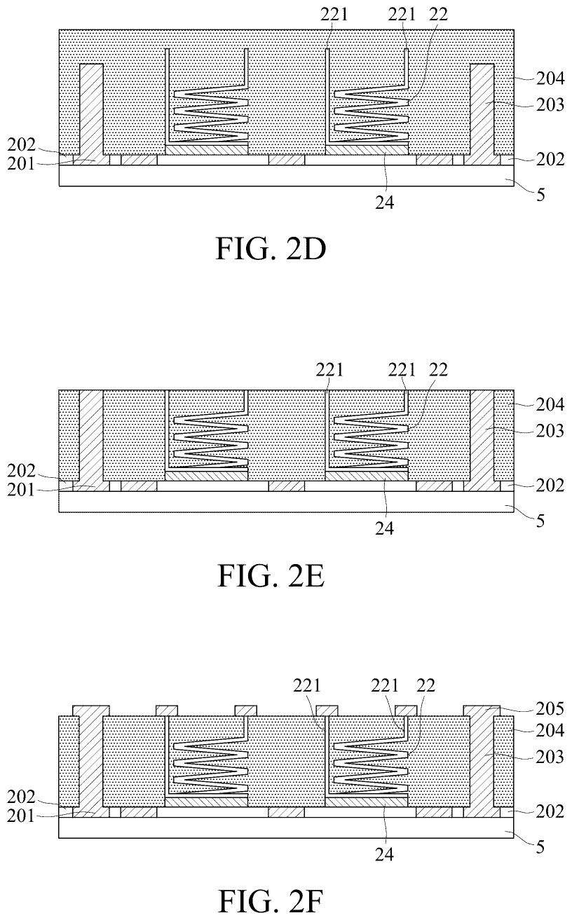

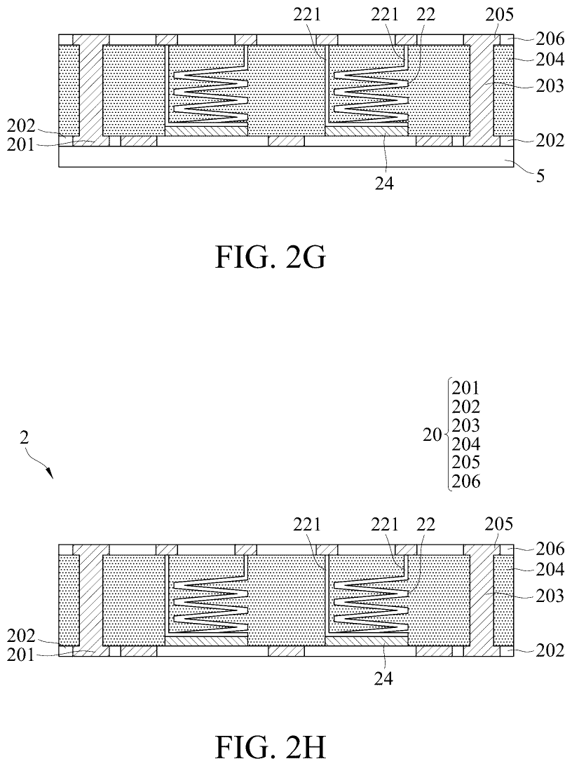

FIG. 2A to FIG. 2H are schematic cross-sectional views illustrating a manufacturing method of a semiconductor packaging substrate structure 2 according to a first embodiment of the present disclosure. In an embodiment, the semiconductor packaging substrate structure 2 of the present disclosure is manufactured by using a packaging substrate technology.

As shown in FIG. 2A, a second patterned wiring layer 201 and a first dielectric layer 202 are formed on a carrier board 5.

The carrier board 5 is made of a semiconductor package carrier material, such as a composite semiconductor package carrier material with rigidity of an insulating material and a metal material (such as stainless steel, copper, copper alloy, aluminum alloy, or a combination thereof, etc.), but not limited thereto.

In an embodiment, a patterned exposure and development process is first performed to form the second patterned wiring layer 201 by electroplating on the carrier board 5, and then the first dielectric layer 202 is formed on the carrier board 5 to cover the second patterned wiring layer 201. Subsequently, a portion of the first dielectric layer 202 is removed to expose the upper surface of the second patterned wiring layer 201 from the upper surface of the first dielectric layer 202. For example, the material of forming the second patterned wiring layer 201 may be copper. The material of forming the first dielectric layer 202 may be a dielectric material such as polybenzoxazole (PBO), polyimide (PI), prepreg (PP), or other dielectric materials. The second patterned wiring layer 201 and the first dielectric layer 202 may be formed by using a redistribution layer (RDL) process.

As shown in FIG. 2B, a patterned exposure and development process is performed to form at least one conductive pillar 203 on the second patterned wiring layer 201 by electroplating, and the conductive pillar 203 is electrically connected to the second patterned wiring layer 201. For example, the material of the conductive pillar 203 is a metal material of copper or a solder material.

As shown in FIG. 2C, at least one winding spiral coil 22 is provided on the first dielectric layer 202.

In an embodiment, a bonding layer 24 is formed on the first dielectric layer 202, and then the winding spiral coil 22 is provided on the bonding layer 24 to enable the winding spiral coil 22 to be more securely bonded to the first dielectric layer 202 by the bonding layer 24. The winding spiral coil 22 has two ends 221, and the winding spiral coil 22 is disposed on the first dielectric layer 202 in a direction where the two ends 221 are away from the bonding layer 24. The bonding layer 24 is an adhesive layer, such as an insulating adhesive or a conductive adhesive material such as silver adhesive.

In an embodiment, the winding spiral coil 22 is formed, for example, by an enameled copper wire, an enameled aluminum wire, or an enameled alloy wire, and the number of windings thereof may be designed according to demand.

As shown in FIG. 2D, a second dielectric layer 204 is formed on the first dielectric layer 202, and the second dielectric layer 204 covers the conductive pillars 203 and the winding spiral coils 22.

The second dielectric layer 204 is formed on the first dielectric layer 202 by lamination or molding. Moreover, the second dielectric layer 204 is made of a dielectric material, such as Ajinomoto Build-up Film (ABF), light-sensitive resin, polyimide (PI), bismaleimide triazine (BT), prepreg (PP) of FR5 (FR stands for flame retardant), molding compound, epoxy molding compound (EMC), or other suitable materials.

As shown in FIG. 2E, a portion of the second dielectric layer 204 is removed by grinding, such that the two ends 221 of the winding spiral coil 22 and one end surface of the conductive pillar 203 are exposed from and flush with the upper surface of the second dielectric layer 204.

As shown in FIG. 2F, a first patterned wiring layer 205 is formed on the second dielectric layer 204, such that the first patterned wiring layer 205 is electrically connected to the end surface of the conductive pillar 203 and the two ends 221 of the winding spiral coil 22, and such that the conductive pillar 203 and the winding spiral coil 22 are located between the second patterned wiring layer 201 and the first patterned wiring layer 205.

The first patterned wiring layer 205 may be made of a conductive metal material, such as copper, silver, nickel, or an alloy thereof. The first patterned wiring layer 205 may be formed by using microphoto-etching technology with an additional photoresist layer (not shown) to perform an exposure and development, etching process, and an electroplating process.

As shown in FIG. 2G, a third dielectric layer 206 is formed on the second dielectric layer 204, such that the third dielectric layer 206 covers the first patterned wiring layer 205. Subsequently, a portion of the third dielectric layer 206 is removed, such that the upper surface of the first patterned wiring layer 205 is exposed from and flush with the upper surface of the third dielectric layer 206, and the partially exposed first patterned wiring layer 205 may serve as an electrical contact pad. The material of forming the third dielectric layer 206 may be, for example, a dielectric material, a light-sensitive or non-light-sensitive organic insulating material, such as a solder-resist material, ABF, and EMC.

As shown in FIG. 2H, the carrier board 5 is removed to obtain the semiconductor packaging substrate structure 2 of the present disclosure. After removal of the carrier board 5, the lower surface of the second patterned wiring layer 201 is exposed from the lower surface of the first dielectric layer 202 and can be used as an electrical contact pad.

In an embodiment, the second patterned wiring layer 201 and the first patterned wiring layer 205, which are electrical contact pads, may be subjected to an anti-tarnish treatment as required to strengthen the anti-tarnish capability of the surface layer.

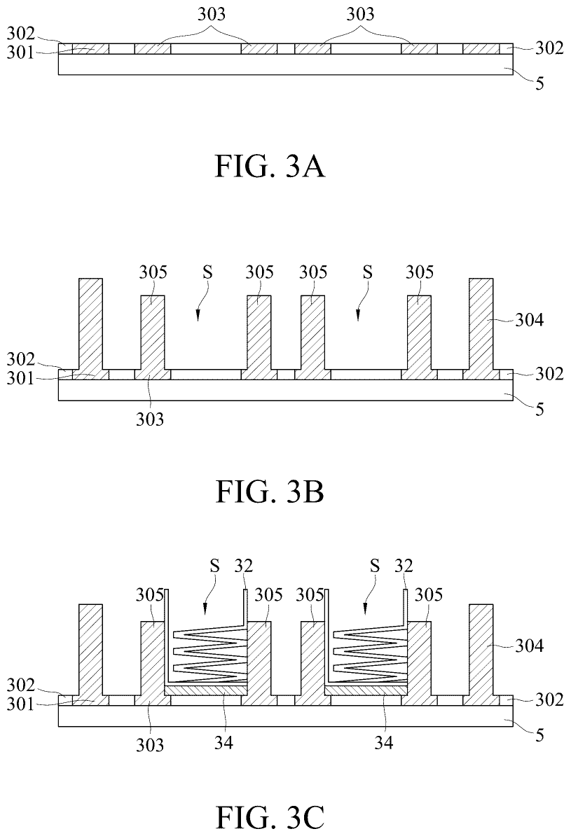

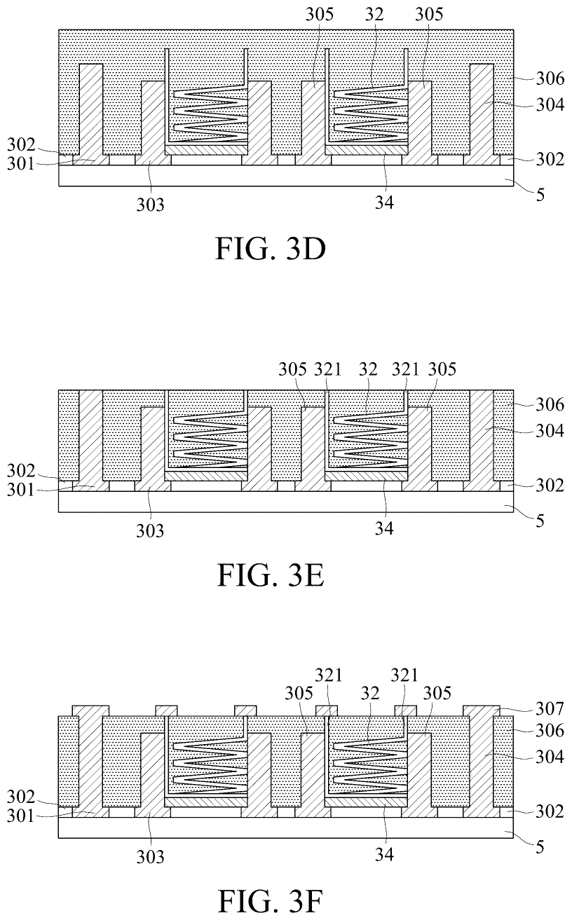

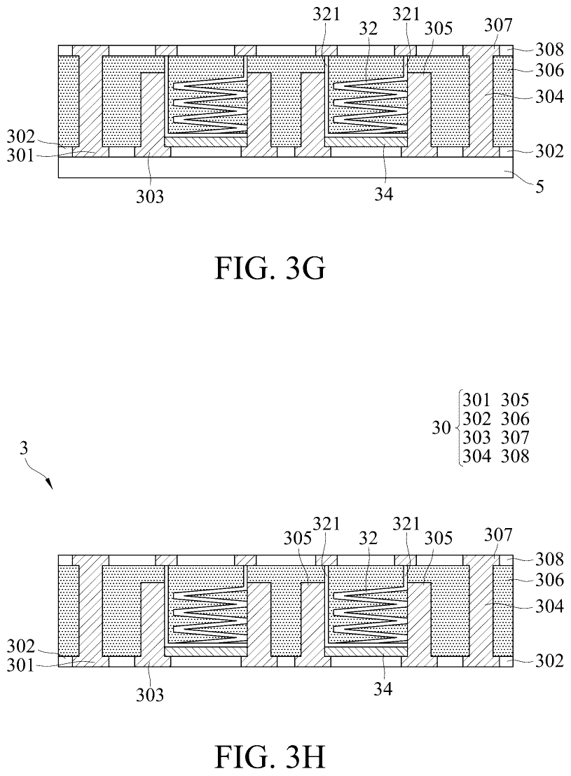

FIG. 3A to FIG. 3H are schematic cross-sectional views illustrating a manufacturing method of a semiconductor packaging substrate structure 3 according to a second embodiment of the present disclosure. The technical difference between the second embodiment of the present disclosure and the first embodiment of the present disclosure lies in limit pillars 305, and the same technical content will not be repeated hereinafter.

As shown in FIG. 3A, a plurality of limit pads 303, a second patterned wiring layer 301, and a first dielectric layer 302 are formed on a carrier board 5.

In an embodiment, a patterned exposure and development process is first performed to simultaneously form the plurality of limit pads 303 and the second patterned wiring layer 301 by electroplating on the carrier board 5. Subsequently, the first dielectric layer 302 is formed on the carrier board 5 to cover the plurality of limit pads 303 and the second patterned wiring layer 301. After that, a portion of the first dielectric layer 302 is removed to expose the upper surface of each of the plurality of limit pads 303 and the upper surface of the second patterned wiring layer 301 from the upper surface of the first dielectric layer 302.

As shown in FIG. 3B, in a patterned exposure and development process, a conductive pillar 304 is formed by electroplating on the second patterned wiring layer 301, and the plurality of limit pillars 305 are formed by electroplating on the plurality of limit pads 303. The plurality of limit pillars 305 form a limit area to provide positioning. For example, the material used to form the conductive pillar 304 and the plurality of limit pillars 305 is copper metal or solder. Further, the height of the conductive pillar 304 and the plurality of limit pillars 305 may or may not be uniform.

In an embodiment, the area surrounded by the plurality of limit pillars 305 may be defined as at least one setting area S of a winding spiral coil 32.

As shown in FIG. 3C, the winding spiral coil 32 is provided in the setting area S, such that the winding spiral coil 32 is accurately limited by the plurality of limit pillars 305 to avoid the occurrence of misalignment.

In an embodiment, a bonding layer 34 is first formed on the first dielectric layer 302 in the setting area S, and then the winding spiral coil 32 is provided on the bonding layer 34 to enable the winding spiral coil 32 to be more securely attached to the first dielectric layer 302 by the bonding layer 34. The winding spiral coil 32 has two ends 321, and the winding spiral coil 32 is disposed on the first dielectric layer 302 in a direction where the two ends 321 are away from the bonding layer 34. The bonding layer 34 is an adhesive layer, such as an insulating adhesive or a conductive adhesive material such as silver adhesive.

In an embodiment, the winding spiral coil 32 is formed, for example, by an enameled copper wire, an enameled aluminum wire, or an enameled alloy wire, and the number of windings thereof may be designed according to demand.

Moreover, the number of the plurality of limit pillars 305 required to define the setting area S can be designed according to the demand. For example, four limit pillars 305 are used to surround the defined setting area S, such that the four limit pillars 305 can be positioned at the four opposite corners of the winding spiral coil 32, thereby limiting the circumference of the winding spiral coil 32. Other numbers of the plurality of limit pillars 305 may also be used to surround the defined setting area S, but not limited thereto. It should be understood that the greater the number of the plurality of limit pillars 305 surrounds the defined setting area S, the greater the accuracy of limiting and positioning of the winding spiral coil 32 is. In addition, the number and position of the plurality of limit pillars 305 may also be designed to match the shape of the winding spiral coil 32, and the present disclosure is not limited thereto.

As shown in FIG. 3D, a second dielectric layer 306 is formed on the first dielectric layer 302, and the second dielectric layer 306 covers the conductive pillars 304, the plurality of limit pillars 305, and the winding spiral coils 32.

As shown in FIG. 3E, a portion of the second dielectric layer 306 is removed by grinding, such that the two ends 321 of the winding spiral coil 32 and one end surface of the conductive pillar 304 are exposed from and flush with the upper surface of the second dielectric layer 306.

As shown in FIG. 3F, a first patterned wiring layer 307 is formed on the second dielectric layer 306, such that the first patterned wiring layer 307 is electrically connected to an end surface of the conductive pillar 304 and the two ends 321 of the winding spiral coil 32, and such that the conductive pillar 304 and the winding spiral coil 32 are located between the second patterned wiring layer 301 and the first patterned wiring layer 307.

The first patterned wiring layer 307 may be made of a conductive metal material, such as copper, silver, nickel, or an alloy thereof. The first patterned wiring layer 307 may be formed by using microphoto-etching technology with an additional photoresist layer (not shown) to perform an exposure and development, etching process, and an electroplating process.

As shown in FIG. 3G, a third dielectric layer 308 is formed on the second dielectric layer 306, such that the third dielectric layer 308 covers the first patterned wiring layer 307. Subsequently, a portion of the third dielectric layer 308 is removed, such that the upper surface of the first patterned wiring layer 307 is exposed from and flush with the upper surface of the third dielectric layer 308, and the partially exposed first patterned wiring layer 307 may serve as an electrical contact pad.

As shown in FIG. 3H, the carrier board 5 is removed to obtain the semiconductor packaging substrate structure 3 of the present disclosure. After removal of the carrier board 5, the lower surface of the second patterned wiring layer 301 is exposed from the lower surface of the first dielectric layer 302 and can be used as an electrical contact pad.

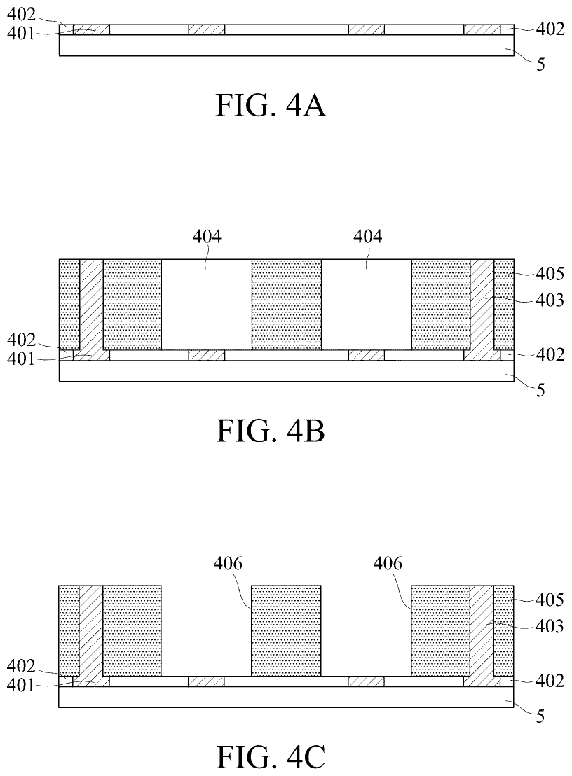

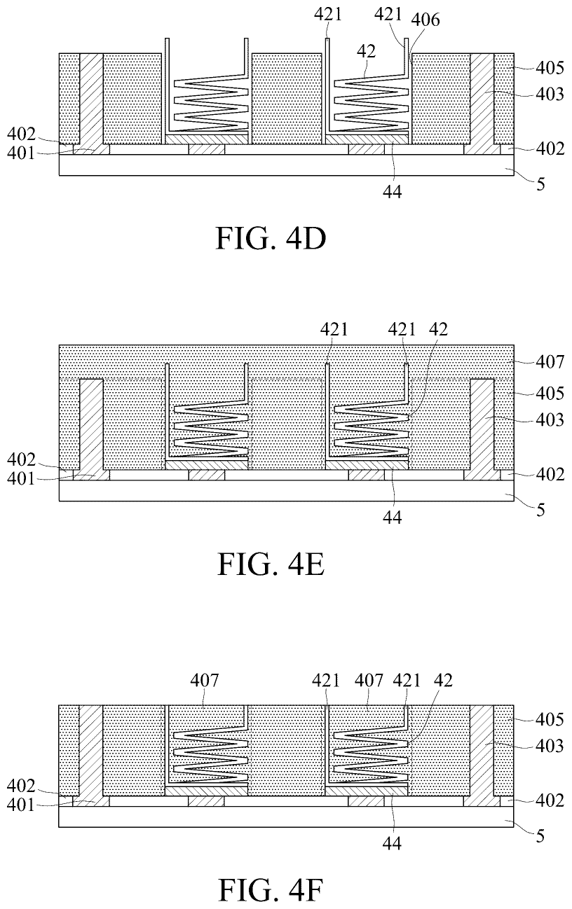

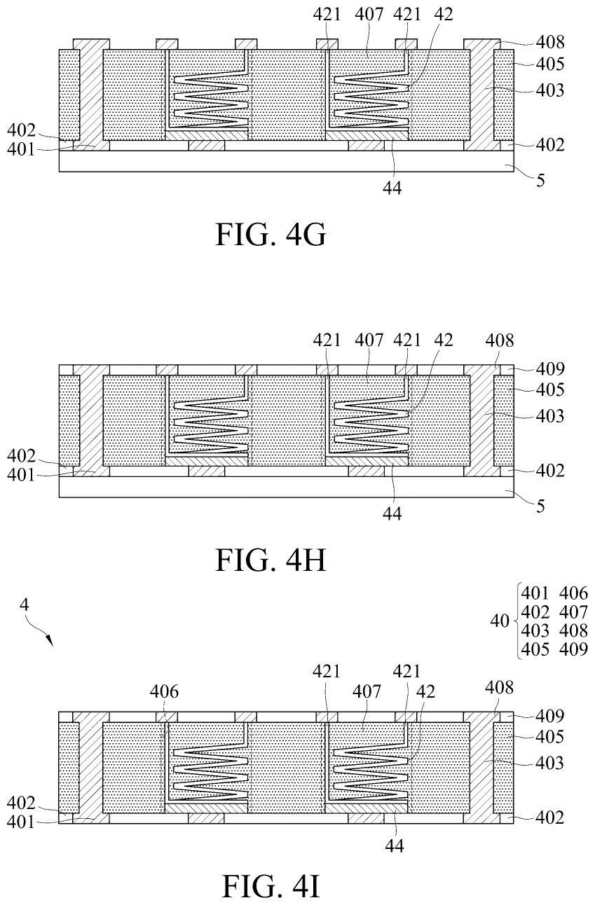

FIG. 4A to FIG. 4I are schematic cross-sectional views illustrating a manufacturing method of a semiconductor packaging substrate structure 4 according to a third embodiment of the present disclosure. The technical difference between the third embodiment of the present disclosure and the second embodiment of the present disclosure is the omission of the limit pillars 305, and a second dielectric layer 405 is used to form limit openings 406 to restrict a winding spiral coil 42, and the same technical content will not be repeated hereinafter.

As shown in FIG. 4A, a second patterned wiring layer 401 and a first dielectric layer 402 are formed on a carrier board 5.

As shown in FIG. 4B, at least one temporary bump 404 is formed on the first dielectric layer 402 by a patterned exposure and development process. At least one conductive pillar 403 is formed by electroplating on the second patterned wiring layer 401 by means of performing a patterned exposure and development process, and the conductive pillar 403 is electrically connected to the second patterned wiring layer 401. Subsequently, the second dielectric layer 405 is formed on the first dielectric layer 402 and the temporary bump 404 such that the temporary bump 404 and the conductive pillar 403 are embedded in the second dielectric layer 405. For example, the temporary bump 404 may be a dry film bump (e.g., a dry film photoresist bump) formed by a patterned exposure and development process, or a metal bump formed by electroplating of a patterned exposure and development process. The second dielectric layer 405 is made of a dielectric material, such as Ajinomoto Build-up Film (ABF), light-sensitive resin, polyimide (PI), bismaleimide triazine (BT), prepreg (PP) of FR5, molding compound, epoxy molding compound (EMC), or other suitable materials, and the second dielectric layer 405 is formed by lamination or molding. Thereafter, a portion of the second dielectric layer 405 is removed to expose an upper surface of the temporary bump 404 and one end surface of the conductive pillar 403.

As shown in FIG. 4C, the temporary bump 404 is removed to form at least one limit opening 406 in the second dielectric layer 405, and the limit opening 406 exposes a portion of the upper surface of the first dielectric layer 402.

As shown in FIG. 4D, the winding spiral coil 42 is provided on the first dielectric layer 402 in the limit opening 406.

In an embodiment, a bonding layer 44 is first formed on the first dielectric layer 402 in the limit opening 406, and then the winding spiral coil 42 is provided on the bonding layer 44 to enable the winding spiral coil 42 to be more securely attached to the first dielectric layer 402 by the bonding layer 44 and is indeed restricted by the limit opening 406. The winding spiral coil 42 has two ends 421, and the winding spiral coil 42 is disposed on the first dielectric layer 402 in a direction where the two ends 421 are away from the bonding layer 44. The bonding layer 44 is an adhesive layer, such as an insulating adhesive or a conductive adhesive material such as silver adhesive.

In an embodiment, the winding spiral coil 42 is formed, for example, by an enameled copper wire, an enameled aluminum wire, or an enameled alloy wire, and the number of windings thereof may be designed according to demand.

Further, the size of the limit opening 406 may be designed according to the size of the winding spiral coil 42, such as equal to or slightly larger than the size of the winding spiral coil 42, such that the winding spiral coil 42 may be effectively restricted by the limit opening 406.

As shown in FIG. 4E, a fourth dielectric layer 407 is formed on the second dielectric layer 405, and the limit openings 406 are filled with the fourth dielectric layer 407, such that the winding spiral coil 42 is embedded in the fourth dielectric layer 407.

In an embodiment, the fourth dielectric layer 407 is made of a dielectric material, which may be the same as the second dielectric layer 405. It should be appreciated that the second dielectric layer 405 and the fourth dielectric layer 407 may be made of different dielectric materials.

As shown in FIG. 4F, a portion of the fourth dielectric layer 407 is removed by grinding, such that the two ends 421 of the winding spiral coil 42 and one end surface of the conductive pillar 403 are exposed from and flush with the upper surface of the second dielectric layer 405 and the upper surface of the fourth dielectric layer 407.

As shown in FIG. 4G, a first patterned wiring layer 408 is formed on the second dielectric layer 405 and the fourth dielectric layer 407, such that the first patterned wiring layer 408 is electrically connected to an end surface of the conductive pillar 403 and the two ends 421 of the winding spiral coil 42, and such that the conductive pillar 403 and the winding spiral coil 42 are located between the second patterned wiring layer 401 and the first patterned wiring layer 408.

As shown in FIG. 4H, a third dielectric layer 409 is formed on the second dielectric layer 405 and the fourth dielectric layer 407, such that the first patterned wiring layer 408 is embedded in the third dielectric layer 409. Subsequently, a portion of the third dielectric layer 409 is removed, such that the upper surface of the first patterned wiring layer 408 is exposed from and flush with the upper surface of the third dielectric layer 409, and the partially exposed first patterned wiring layer 408 may serve as an electrical contact pad.

As shown in FIG. 4I, the carrier board 5 is removed to obtain the semiconductor packaging substrate structure 4 of the present disclosure. After removal of the carrier board 5, the lower surface of the second patterned wiring layer 401 is exposed from the lower surface of the first dielectric layer 402 and can be used as an electrical contact pad.

With reference to FIG. 2H, it can be seen that one structural embodiment of the present disclosure provides a semiconductor packaging substrate structure 2, which comprises a circuit build-up structure 20 and at least one winding spiral coil 22.

In an embodiment, the circuit build-up structure 20 includes a first patterned wiring layer 205, a second patterned wiring layer 201, at least one conductive pillar 203, a first dielectric layer 202, a second dielectric layer 204, and a third dielectric layer 206. The first dielectric layer 202, the second dielectric layer 204, and the third dielectric layer 206 are stacked from bottom to top to form a single unit. In addition, the first patterned wiring layer 205 is embedded in the third dielectric layer 206. The second patterned wiring layer 201 is embedded in the first dielectric layer 202. The conductive pillar 203 is embedded in the second dielectric layer 204, and two ends of the conductive pillar 203 are electrically connected to the first patterned wiring layer 205 and the second patterned wiring layer 201, respectively. The winding spiral coil 22 is bonded to and erected on the upper surface of the first dielectric layer 202 by a bonding layer 24 and embedded in the second dielectric layer 204. Two ends 221 of the winding spiral coil 22 are electrically connected to the first patterned wiring layer 205.

In an embodiment, the upper surface of the first patterned wiring layer 205 is exposed from and flush with the upper surface of the third dielectric layer 206, and the partially exposed first patterned wiring layer 205 may serve as an electrical contact pad. The lower surface of the second patterned wiring layer 201 is exposed from and flush with the lower surface of the first dielectric layer 202, and the partially exposed second patterned wiring layer 201 may be used as an electrical contact pad.

Referring to FIG. 3H, it can be seen that another structural embodiment of the present disclosure provides a semiconductor packaging substrate structure 3, which comprises a circuit build-up structure 30 and at least one winding spiral coil 32.

In an embodiment, the circuit build-up structure 30 includes a first patterned wiring layer 307, a second patterned wiring layer 301, at least one conductive pillar 304, a plurality of limit pads 303, a plurality of limit pillars 305, a first dielectric layer 302, a second dielectric layer 306, and a third dielectric layer 308. The first dielectric layer 302, the second dielectric layer 306, and the third dielectric layer 308 are stacked from bottom to top to form a single unit. In addition, the first patterned wiring layer 307 is embedded in the third dielectric layer 308. The second patterned wiring layer 301 is embedded in the first dielectric layer 302. The conductive pillar 304 is embedded in the second dielectric layer 306, and two ends of the conductive pillar 304 are electrically connected to the first patterned wiring layer 307 and the second patterned wiring layer 301, respectively. The plurality of limit pads 303 are embedded in the first dielectric layer 302. The plurality of limit pillars 305 are bonded to and erected on the plurality of limit pads 303 and are embedded in the second dielectric layer 306, and the plurality of limit pillars 305 may frame a limit area. The winding spiral coil 32 is bonded to and erected on the upper surface of the first dielectric layer 302 by a bonding layer 34 and is embedded in the second dielectric layer 306 and in the limit area framed by the plurality of limit pillars 305, and two ends 321 of the winding spiral coil 32 are electrically connected to the first patterned wiring layer 307.

In an embodiment, the upper surface of the first patterned wiring layer 307 is exposed from and flush with the upper surface of the third dielectric layer 308, and the partially exposed first patterned wiring layer 307 may serve as an electrical contact pad. The lower surface of the second patterned wiring layer 301 is exposed from and flush with the lower surface of the first dielectric layer 302, and the partially exposed second patterned wiring layer 301 may be used as an electrical contact pad.

Referring to FIG. 4I, it can be seen that another structural embodiment of the present disclosure provides a semiconductor packaging substrate structure 4, which comprises a circuit build-up structure 40 and at least one winding spiral coil 42.

In an embodiment, the circuit build-up structure 40 includes a first patterned wiring layer 408, a second patterned wiring layer 401, at least one conductive pillar 403, at least one limit opening 406, a first dielectric layer 402, a second dielectric layer 405, a fourth dielectric layer 407, and a third dielectric layer 409. The first dielectric layer 402, the second dielectric layer 405, the fourth dielectric layer 407, and the third dielectric layer 409 are stacked from bottom to top to form a single unit. The first patterned wiring layer 408 is embedded in the third dielectric layer 409. The second patterned wiring layer 401 is embedded in the first dielectric layer 402. The conductive pillar 403 is embedded in the second dielectric layer 405, and two ends of the conductive pillar 403 are electrically connected to the first patterned wiring layer 408 and the second patterned wiring layer 401, respectively. The limit opening 406 is formed in the second dielectric layer 405 and penetrates through the upper surface and lower surface of the second dielectric layer 405 to frame a limit area, and the limit opening 406 is filled with the fourth dielectric layer 407. The winding spiral coil 42 is bonded to and erected on the upper surface of the first dielectric layer 402 by means of a bonding layer 44 and is embedded in the fourth dielectric layer 407 within the limit area framed by the limit opening 406. In addition, two ends 421 of the winding spiral coil 42 are electrically connected to the first patterned wiring layer 408.

In an embodiment, the upper surface of the first patterned wiring layer 408 is exposed from and flush with the upper surface of the third dielectric layer 409, and the partially exposed first patterned wiring layer 408 may serve as an electrical contact pad. The lower surface of the second patterned wiring layer 401 is exposed from and flush with the lower surface of the first dielectric layer 402, and the partially exposed second patterned wiring layer 401 may be used as an electrical contact pad.

The aforesaid structural embodiments of the present disclosure have winding spiral coils 22, 32, 42, specifically formed by an enameled copper wire, an enameled aluminum wire, or an enameled alloy wire, and the number of windings thereof may be designed according to demand. The bonding layer 24, 34, 44 is an adhesive layer, such as an insulating adhesive or a conductive adhesive material such as silver adhesive.

In summary, in the semiconductor packaging substrate structure and the manufacturing method thereof, by directly providing the winding spiral coil, the present disclosure can avoid the time-consuming, costly, and unstable quality problem of manufacturing multi-layer plate coil by the conventional circuit build-up method. The winding spiral coil of the present disclosure can be manufactured independently and then disposed into the semiconductor packaging substrate structure, thereby avoiding the problem of poor product yield caused by the failure of one of the coils in the conventional multi-layer plate coil. Moreover, in addition to directly disposing the winding spiral coil in the semiconductor packaging substrate structure, the present disclosure can also dispose limit pillars or limit openings in the dielectric layer in order to dispose the winding spiral coils accurately, thereby effectively avoid misalignment of the winding spiral coils. The semiconductor packaging substrate structure of the present disclosure with winding spiral coils is superior in performance to plate coils and can be effectively applied to coil structures in optical image stabilization voice coil motors (OIS VCMs), loudspeakers, miniature motors, miniature inductors, and protective devices for electronic components.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor packaging substrate structure with winding spiral coils, comprising:
a circuit build-up structure comprising at least one first patterned wiring layer, a first dielectric layer, a second dielectric layer, and a third dielectric layer, wherein the second dielectric layer is stacked and bonded to an upper surface of the first dielectric layer, the third dielectric layer is stacked and bonded to an upper surface of the second dielectric layer, a first patterned wiring layer is embedded within the third dielectric layer, and an upper surface of the first patterned wiring layer is exposed from an upper surface of the third dielectric layer; and
at least one winding spiral coil provided on the upper surface of the first dielectric layer, embedded within the second dielectric layer, and electrically connected to the first patterned wiring layer, wherein a body of the winding spiral coil is an enameled copper wire, an enameled aluminum wire, or an enameled alloy wire.

2. The semiconductor packaging substrate structure of claim 1, further comprising: at least one second patterned wiring layer embedded within the first dielectric layer, and at least one conductive pillar embedded within the second dielectric layer, wherein an upper surface and a lower surface of the second patterned wiring layer are exposed from the upper surface and a lower surface of the first dielectric layer, respectively, and the conductive pillar is electrically connected to the first patterned wiring layer and the second patterned wiring layer.

3. The semiconductor packaging substrate structure of claim 1, further comprising: a plurality of limit pillars embedded within the second dielectric layer, wherein the plurality of limit pillars are framed around a circumference of the winding spiral coil.

4. The semiconductor packaging substrate structure of claim 3, further comprising: at least one second patterned wiring layer embedded within the first dielectric layer, and at least one conductive pillar embedded within the second dielectric layer, wherein an upper surface and a lower surface of the second patterned wiring layer are exposed from the upper surface and a lower surface of the first dielectric layer, respectively, and the conductive pillar is electrically connected to the first patterned wiring layer and the second patterned wiring layer.

5. The semiconductor packaging substrate structure of claim 3, further comprising: a plurality of limit pads embedded within the first dielectric layer, wherein the plurality of limit pillars are bonded to and erected on upper surfaces of the plurality of limit pads.

6. The semiconductor packaging substrate structure of claim 5, further comprising: at least one second patterned wiring layer embedded within the first dielectric layer, and at least one conductive pillar embedded within the second dielectric layer, wherein an upper surface and a lower surface of the second patterned wiring layer are exposed from the upper surface and a lower surface of the first dielectric layer, respectively, and the conductive pillar is electrically connected to the first patterned wiring layer and the second patterned wiring layer.

7. The semiconductor packaging substrate structure of claim 1, further comprising: at least one limit opening formed within the second dielectric layer and accordingly accommodating the winding spiral coil, wherein the limit opening further comprises a fourth dielectric layer covering the winding spiral coil and filling the limit opening.

8. The semiconductor packaging substrate structure of claim 7, further comprising: at least one second patterned wiring layer embedded within the first dielectric layer, and at least one conductive pillar embedded within the second dielectric layer, wherein an upper surface and a lower surface of the second patterned wiring layer are exposed from the upper surface and a lower surface of the first dielectric layer, respectively, and the conductive pillar is electrically connected to the first patterned wiring layer and the second patterned wiring layer.

9. A method of manufacturing a semiconductor packaging substrate structure with winding spiral coils, comprising:
providing a carrier board having a rigidity;
forming a first dielectric layer on the carrier board;
providing at least one winding spiral coil, and disposing the winding spiral coil on the first dielectric layer, wherein a body of the winding spiral coil is an enameled copper wire, an enameled aluminum wire, or an enameled alloy wire;
forming a second dielectric layer on the first dielectric layer to cover the winding spiral coil;
removing a portion of the second dielectric layer to expose two ends of the winding spiral coil;
forming a first patterned wiring layer by electroplating on the second dielectric layer by means of a patterned exposure and development process, wherein the first patterned wiring layer is electrically connected to the two ends of the winding spiral coil;
forming a third dielectric layer on the second dielectric layer to cover the first patterned wiring layer;
removing a portion of the third dielectric layer to expose an upper surface of the first patterned wiring layer; and
removing the carrier board.

10. The method of claim 9, further comprising:
prior to forming the first dielectric layer, performing a patterned exposure and development process to form a second patterned wiring layer by electroplating, and after forming the first dielectric layer to cover the second patterned wiring layer, removing a portion of the first dielectric layer to expose an upper surface of the second patterned wiring layer from an upper surface of the first dielectric layer;
prior to providing the winding spiral coil, performing a patterned exposure and development process to form at least one conductive pillar by electroplating, wherein the conductive pillar is electrically connected to the second patterned wiring layer;
exposing an end surface of the conductive pillar while removing the portion of the second dielectric layer to expose the two ends of the winding spiral coil; and
electrically connecting the first patterned wiring layer to the two ends of the winding spiral coil and electrically connecting the first patterned wiring layer to the conductive pillar while forming the first patterned wiring layer by electroplating.

11. The method of claim 9, further comprising:
prior to forming the first dielectric layer, performing a patterned exposure and development process to form a plurality of limit pads by electroplating, and after forming the first dielectric layer to cover the carrier board and the plurality of limit pads, removing a portion of the first dielectric layer to expose upper surfaces of the plurality of limit pads from an upper surface of the first dielectric layer; and
forming a plurality of limit pillars by electroplating on the upper surfaces of the plurality of limit pads by means of a patterned exposure and development process, wherein an area surrounded by the plurality of limit pillars defines a setting area of the winding spiral coil.

12. The method of claim 11, further comprising:
forming a second patterned wiring layer by electroplating while forming the plurality of limit pads by electroplating, and exposing an upper surface of the second patterned wiring layer while removing the portion of the first dielectric layer to expose the upper surfaces of the plurality of limit pads;
forming at least one conductive pillar on the upper surface of the second patterned wiring layer by electroplating while forming the plurality of limit pillars by electroplating;
exposing an end surface of the conductive pillar while removing the portion of the second dielectric layer to expose the two ends of the winding spiral coil; and
electrically connecting the first patterned wiring layer to the two ends of the winding spiral coil and electrically connecting the first patterned wiring layer to the conductive pillar while forming the first patterned wiring layer by electroplating.

13. A method of manufacturing a semiconductor packaging substrate structure, comprising:
providing a carrier board having a rigidity;
forming a first dielectric layer on the carrier board;
forming at least one temporary bump on an upper surface of the first dielectric layer by a patterned exposure and development process;
forming a second dielectric layer on the first dielectric layer and the temporary bump, wherein the temporary bump is embedded within the second dielectric layer;
removing a portion of the second dielectric layer to expose an upper surface of the temporary bump;
removing the temporary bump to form at least one limit opening in the second dielectric layer;
providing at least one winding spiral coil, and disposing the winding spiral coil within the limit opening, wherein a body of the winding spiral coil is an enameled copper wire, an enameled aluminum wire, or an enameled alloy wire;
forming a fourth dielectric layer on the second dielectric layer, wherein the limit opening is filled by the fourth dielectric layer, and the winding spiral coil is embedded within the fourth dielectric layer;
removing a portion of the fourth dielectric layer to expose two ends of the winding spiral coil and an upper surface of the second dielectric layer;
forming a first patterned wiring layer by electroplating on the upper surface of the second dielectric layer and an upper surface of the fourth dielectric layer by means of a patterned exposure and development process, wherein a portion of the first patterned wiring layer is electrically connected to the two ends of the winding spiral coil;
forming a third dielectric layer on the upper surface of the second dielectric layer and the upper surface of the fourth dielectric layer, wherein the first patterned wiring layer is embedded within the third dielectric layer;
removing a portion of the third dielectric layer to expose an upper surface of the first patterned wiring layer; and
removing the carrier board.

14. The method of claim 13, wherein the temporary bump is a dry film photoresist bump formed by the patterned exposure and development process.

15. The method of claim 13, wherein the temporary bump is a metal bump formed by electroplating by means of the patterned exposure and development process.

16. The method of claim 13, further comprising:
prior to forming the first dielectric layer, performing a patterned exposure and development process to form a second patterned wiring layer by electroplating, and after forming the first dielectric layer to cover the second patterned wiring layer, removing a portion of the first dielectric layer to expose an upper surface of the second patterned wiring layer from the upper surface of the first dielectric layer;
prior to forming the second dielectric layer, forming at least one conductive pillar electrically connected to the second patterned wiring layer by electroplating;
exposing an end surface of the conductive pillar while removing the portion of the second dielectric layer to expose the upper surface of the temporary bump; and
electrically connecting the first patterned wiring layer to the two ends of the winding spiral coil and electrically connecting the first patterned wiring layer to the conductive pillar while forming the first patterned wiring layer by electroplating.
